(19) United States
(12) Patent Application Publication
(10) Pub. No.: US 2009/0233086 A1
(43) Pub. Date: Sep. 17, 2009

(54) METAL OXIDE MICROPARTICLES, TRANSPARENT CONDUCTIVE FILM, AND DISPERSION

(75) Inventor: Hiroyuki HIRAI, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/389,668

(22) Filed: Feb. 20, 2009

(30) Foreign Application Priority Data
Mar. 17, 2008 (JP) 2008-067361

(51) Int. Cl. B32B 5/16; B32B 9/00; B32B 15/02; B82B 1/00

(52) U.S. Cl. 428/328; 428/402; 977/762

(57) ABSTRACT

The present invention provides a transparent conductive film including metal oxide microparticles having a mean particle diameter of 2 nm to 1,000 nm and silver nanowires having a minor axis diameter of 2 nm to 100 nm and an aspect ratio of 10 to 200.

### BACKGROUND OF THE INVENTION

1. Field of the Invention

The present invention relates to novel sheet-shaped metal oxide microparticles, and to a transparent conductive film and a dispersion that have high transparency and conductivity, and excel in storage stability.

2. Description of the Related Art

As a transparent conductive film, antimony- or fluorine-doped tin oxide films, tin- or zinc-doped indium oxide films, aluminum- or gallium-doped zinc oxide films, and the like have been known. The transparent conductive films are applied to, for example, transparent electrodes in liquid crystal display elements, plasma emission elements, electronic papers, etc., transparent electrodes for solar cells, heat-reflecting films, antistatic films, transparent heating elements, touch panels, electromagnetic wave shielding films, and the like.

In general, the transparent conductive film is produced by vapor deposition methods such as sputtering method, chemical vapor deposition (CVD) method, and vacuum deposition method. In some cases, however, coating methods using a conductive dispersion are employed to produce transparent conductive films with ease and at low cost. In particular, coating methods are preferable when a large-area transparent conductive film is produced or when a plastic substrate with low thermal resistance is used. Japanese Patent Application Laid-Open (JP-A) No. 06-279755 discloses a conductive dispersion in which a fine powder of tin-doped indium oxide, or indium tin oxide (ITO), and an alkyl silicate as a binder are dispered in a polar solvent which consists mainly of N-methyl-2-pyrrolidone. This dispersion is applied, dried, and then baked at a temperature not exceeding 200° C. to obtain a film having a surface resistivity of 103 to 10⁵ Ω/square. Due to high resistivity, applications thereof are limited.

As a conductive dispersion that enables a lower surface resistivity, JP-A Nos. 09-286936 and 11-45619 disclose a conductive dispersion using metal microparticles and a conductive dispersion using metal microparticles and a metal oxide such as ITO in combination. Although the use of metal microparticles reduces the surface resistivity to the order of 10² Ω/square, transparency is reduced.

JP-A No. 2004-196923, International Publication No. WO07/022226, and “ACCOUNTS OF CHEMICAL RESEARCH, Vol. 40, 1067-1076 (2007)” disclose a transparent conductive film using silver nanowires. In these proposals, a conductive material is silver alone. Therefore, the transparent conductive films disclosed in these proposals are inferior in storage stability.

### BRIEF SUMMARY OF THE INVENTION

An object of the present invention is to provide novel sheet-shaped metal oxide microparticles having a width (minor axis length) and a length (major axis length) of 0.05 μm to 100 μm, respectively and having a thickness of 2 nm to 1,000 nm, a transparent conductive film which has high transparency and conductivity and excels in flexibility and storage stability, and a dispersion.

The present invention provides the following in order to solve the above-described problems.

<1> A transparent conductive film including: metal oxide microparticles; and silver nanowires, wherein the metal oxide microparticles have a mean particle diameter of 2 nm to 1,000 nm, and the silver nanowires have a minor axis diameter of 2 nm to 100 nm and an aspect ratio of 10 to 200.

<2> The transparent conductive film according to <1>, wherein a mass ratio of the silver nanowires to the metal oxide microparticles is 0.001 to 1.

<3> The transparent conductive film according to <1>, wherein the metal oxide microparticles are metal oxides each of which contains at least two metals selected from the group consisting of Zn, Al, Ga, In, Sn and Sb.

<4> The transparent conductive film according to <1> above, wherein the silver nanowires are present in an amout of 0.01 g to 1 g per 1 m².

<5> A transparent conductive film including sheet-shaped metal oxide microparticles, wherein a width and a length of the sheet-shaped metal oxide microparticles are 0.05 μm to 100 μm, respectively, and a thickness of the sheet-shaped metal oxide microparticles is 2 nm to 1,000 nm.

<6> The transparent conductive film according to <5> above, further including silver nanowires.

<7> The transparent conductive film according to <6> above, wherein the silver nanowires have a width of 2 nm to 100 nm and an aspect ratio of 10 to 200.

<8> The transparent conductive film according to <6> above, wherein a mass ratio of the silver nanowires to the metal oxide microparticles is 0.001 to 1.

<9> The transparent conductive film according to <5> above, wherein the metal oxide microparticles are metal oxides each of which contains at least two metals selected from the group consisting of Zn, Al, Ga, In, Sn and Sb.

<10> The transparent conductive film according to <6> above, wherein the silver nanowires are present in an amout of 0.01 g to 1 g per 1 m².

<11> A metal oxide microparticle, wherein the metal oxide microparticle has a sheet shape, and wherein a width and a length of the metal oxide microparticle are 0.05 μm to 100 μm, respectively, and a thickness of the metal oxide microparticle is 2 nm to 1,000 nm.

<12> The metal oxide microparticle according to <11> above, wherein the metal oxide microparticle is a metal oxide which contains at least two metals selected from the group consisting of Zn, Al, Ga, In, Sn and Sb.

<13> A dispersion including sheet-shaped metal oxide microparticles and silver nanowires, wherein a width and a length of the sheet-shaped metal oxide microparticles are 0.05 μm to 100 μm, respectively, and a thickness of the sheet-shaped metal oxide microparticles is 2 nm to 1,000 nm, and wherein the silver nanowires have a minor axis diameter of 2 nm to 100 nm and an aspect ratio of 10 to 200.

<14> The dispersion according to <13> above, which is applicable for formation of an electro-luminescence (EL) element.

<15> A device including a transparent conductive film, wherein the transparent conductive film includes metal oxide microparticles and silver nanowires, wherein the metal oxide microparticles have a mean particle diameter of 2 nm to 1,000 nm, and the silver nanowires have a minor axis diameter of 2 nm to 100 nm and an aspect ratio of 10 to 200.

<16> The device according to <15> above, which is an electro-luminescence (EL) element.

<17> A device including a transparent conductive film, wherein the transparent conductive film includes sheet-shaped metal oxide microparticles, wherein a width and a length of the sheet-shaped metal oxide microparticles are 0.05 μm to 100 μm, respectively, and a thickness of the sheet-shaped metal oxide microparticles is 2 nm to 1,000 nm,

<18> The device according to <17> above, which is an electro-luminescence (EL) element.

<19> A device including sheet-shaped metal oxide microparticles, wherein a width and a length of the sheet-shaped metal oxide microparticles are 0.05 μm to 100 μm, respectively, and a thickness of the sheet-shaped metal oxide microparticles is 2 nm to 1,000 nm.

<20> The device according to <19> above, which is an electro-luminescence (EL) element.

<21> A device, which is produced using a dispersion, wherein the dispersion includes sheet-shaped metal oxide microparticles and silver nanowires, wherein a width and a length of the sheet-shaped metal oxide microparticles are 0.05 μm to 100 μm, respectively, and a thickness of the sheet-shaped metal oxide microparticles is 2 nm to 1,000 nm, and wherein the silver nanowires have a minor axis diameter of 2 nm to 100 nm and an aspect ratio of 10 to 200.

<22> The device according to <21> above, which is an electro-luminescence (EL) element.

The present invention can solve the above-described problems, and can provide: novel sheet-shaped metal oxide microparticles having a width and a length of 0.05 μm to 100 μm, respectively and having a thickness of 2 nm to 1,000 nm; a transparent conductive film which has high transparency and conductivity and excels in flexibility and storage stability; and a dispersion.

### BRIEF DESCRIPTION OF THE DRAWINGS

FIG. 1 is a transmission electron microscope (TEM) image of metal oxide microparticles 1 (AZO nanosheet).

FIG. 2 is a transmission electron microscope (TEM) image of silver nanowires 1.

### DETAILED DESCRIPTION OF THE INVENTION

### (Sheet-Shaped Metal Oxide Microparticle(s))

The material, shape, and the like of sheet-shaped metal oxide microparticle(s) of the present invention is(are) not particularly limited and can be appropriately selected depending on the purpose as long as a width (minor axis length) and a length (major axis length) of the sheet-shaped metal oxide microparticle(s) are 0.05 μm to 100 μm, respectively and a thickness thereof is 2 nm to 1,000 nm. The sheet-shaped metal oxide microparticle(s) may be quadrilateral, rectangular, lozenged, polygonal, or the like.

The width (minor axis length) and the length (major axis length) of the metal oxide microparticle(s) are each 0.05 μm to 100 μm, preferably 0.05 μm to 5 μm. When the width and length are less than 0.05 μm, the resistance of the coated film may become large. When the width and length are more than 100 μm, the metal oxide microparticle(s) may bend when preparing dispersion due to weak physical strength thereof.

The thickness of the metal oxide microparticle(s) is 2 nm to 1,000 nm, preferably 5 nm to 500 nm. When the thickness is less than 2 nm, the metal oxide microparticle(s) may bend when preparing dispersion due to weak physical strength thereof. When the thickness is more than 1,000 nm, transparency of the coated film may be deteriorated.

The width (minor axis length) and the length (major axis length) of the metal oxide microparticle(s) can be determined through observation with transmission electron microscope (TEM). The thickness of the metal oxide microparticle(s) can be determined through cross-sectional observation with atomic force microscope (AFM).

The sheet-shaped metal oxide microparticle(s) includes those having thick flat-plate shape and those having a shape close to a rectangular parallelepiped as long as the above-noted range. Particularly preferred shape is a thin flat-plate shape such that the thickness is in the range of 2 nm to 1,000 nm and is ⅕ or less of the width or length of the microparticles, whichever is the smaller.

The crystal may be a single crystal or a polycrystal, or may be aggregates of flat plate-shaped single-crystal microparticles. In this case, crystallite size is preferably from 2 nm to 100 nm, more preferably from 2 nm to 50 nm. When the metal oxide microparticles consist of the flat plate-shaped single crystals, the particle size is preferably such that the size of the flat-plate is 0.05 μm to 100 μm, and the thickness thereof is 2 nm to 50 nm.

The metal oxide, which constitutes the metal oxide microparticle(s), is not particularly limited and can be appropriately selected depending on the purpose. Oxides containing at least two metals selected from the group consisting of Zn, Al, Ga, In, Sn and Sb, are preferable, and specific examples thereof include AZO (Al-doped ZnO), indium tin oxide (ITO), antimony tin oxide (ATO), GZO (Ga-doped ZnO), indium zinc oxide (IZO), and the like.

AZO nanosheet(s) as the metal oxide microparticle(s) can be produced, for example, as follows.

Zinc acetate dihydrate and aluminum (III) isopropoxide are dissolved in ethylene glycol. To this solution, is added sodium hydroxide dissolved in ethylene glycol. The mixture is stirred for 8 hours while heating at 170° C. After cooling to room temperature, ethanol is added to the mixture, followed by centrifugation to thereby purify the product. Then, the product is dispersed in a mixture of 60 vol. % isopropanol, 20 vol. % N-methylpyrrolidone, and 20 vol. % ethylene glycol using a nanomizer (product of Tokai Corporation) to prepare a dispersion containing AZO.

By the observation of the resultant dispersion with a transmission electron microscope (TEM), it is found that nanosheet(s) is(are) formed that has(have) a width (minor axis length) and a length (major axis length) of 0.05 μm to 10 μm, and a thickness of 50 nm to 200 nm.

The sheet-shaped metal oxide microparticle(s) of the present invention can be used for various applications, but particularly preferably used for below-described transparent conductive film of the present invention, dispersion of the present invention, and the like.

### (Transparent Conductive Film)

The transparent conductive film of the present invention, in a first embodiment, includes metal oxide microparticles having a mean particle diameter of 2 nm to 1,000 nm and silver nanowires having a width (minor axis diameter) of 2 nm to 100 nm and an aspect ratio of 10 to 200 and includes, if necessary, other components.

The transparent conductive film of the present invention, in a second embodiment, includes sheet-shaped metal oxide microparticles having a width (minor axis length) and a length (major axis length) of 0.05 μm to 100 μm, respectively and having a thickness of 2 nm to 1,000 nm, and includes, if necessary, other components, for example, silver nanowires. The silver nanowires are preferably the silver nanowires of the present invention described below.

For the sheet-shaped metal oxide microparticles having a width (minor axis length) and a length (major axis length) of 0.05 μm to 100 μm, respectively and having a thickness of 2 nm to 1,000 nm, the sheet-shaped metal oxide microparticles of the present invention can be used.

—Metal Oxide Microparticles having a Mean Particle Diameter of 2 nm to 1,000 nm—

The metal oxide microparticles are not particularly limited as long as they have a mean particle diameter of 2 nm to 1,000 nm, preferably of 2 nm to 100 nm. The metal oxide microparticles can be appropriately selected depending on the purpose; for example, the metal oxide microparticles of the present invention can be used. When the metal oxide microparticles are a polycrystal, the mean particle diameter refers to a crystallite size.

### —Silver Nanowires—

The silver nanowires have a width (minor axis diameter) of 2 nm to 100 nm, preferably 5 nm to 80 nm. When the width (minor axis diameter) is less than 2 nm, stability of dispersion may be deteriorated. When the width (minor axis diameter) is more than 100 nm, transparency of coated film may be damged.

The silver nanowires have an aspect ratio of 10 to 200, preferably 10 to 100. When the aspect ratio is less than 10, conductivity and transparency may not be achieved simultaneously. When the aspect ratio is more than 200, stability of dispersion may be deteriorated.

The width (minor axis diameter) and aspect ratio can be determined using transmission electron microscope (TEM) and scanning electron microscope (SEM). For example, the width (minor axis diameter) of cylindrical metal particles is measured through observation with TEM, the length (major axis length) is measured through observation with SEM, and the aspect ratio can be calculated.

The method for producing the silver nanowires is not particularly limited and can be appropriately selected according to the purpose; examples thereof include a method by N. R. Jana, L. Gearheart and C. J. Murphy (Chem. Commun., 2001, pp 617-618), a method by C. Ducamp-Sanguesa, R. Herrera-Urbina, and M. Figlarz (J. Solid State Chem., 100. 1992, pp 272-280), and the like.

In the transparent conductive film of the present invention, the mass ratio of the silver nanowires to the metal oxide microparticles is preferably 0.001 to 1, more preferably 0.01 to 0.1. When the mass ratio is less than 0.001, conductivity may be deteriorated. When the mass ratio is more than 1, transparency may be damged.

The coating amount of the silver nanowires is preferably 0.01 g to 1 g per 1 m², more preferably 0.05 g to 0.8 g per 1 m². When the coating amount is less than 0.01 g, conductivity may be deteriorated. When the coating amount is more than 1 g, transparency may be damged.

The transparent conductive film of the present invention has a surface resistivity of 1×10⁷ Ω/square or less, preferably 1×10³ Ω/square or less.

The surface resistivity can be determined, for example, by a four-probe method.

The light transmittance of the transparent conductive film of the present invention is preferably 70% or more, more preferably 80% or more.

The transmittance can be determined, for example, by a spectrophotometer (UV2400-PC, product of Shimadzu Corporation).

### (Dispersion)

The dispersion of the present invention includes the sheet-shaped metal oxide microparticles of the present invention, silver nanowires having a width (minor axis diameter) of 2 nm to 100 nm and an aspect ratio of 10 to 200, and includes a dispersion medium and, if necessary, other components.

In the dispersion, the mass ratio of the silver nanowires to the metal oxide microparticles is preferably 0.001 to 1, more preferably 0.01 to 0.1.

The dispersion solvent for forming the dispersion can be arbitrarily selected depending on the coating method or on the purpose, including hydrophilic ones such as water and alcohols and hydrophilic ones such as alkanes and esters. In order to make drying easier, those having a boiling point of 250° C. or less, particularly those having a boiling point of 200° C. or less are preferred. The dispersion solvents may be used alone or in combination.

The dispersion has a viscosity at 20° C. of 0.5 mPa·s to 100 mPa·s, more preferalby 1 mPa·s to 50 mPa·s.

If necessary, the present dispersion may contain various additives such as a resin component, a surfactant, a hardener, a polymerizable compound, an antioxidant and a viscosity adjuster.

The dispersion of the present invention is not particularly limited and can be appropriately selected according to the purpose. The present dispersion can be preferably used, for example, for formation of transparent conductive films of various devices. Especially, the present dispersion can be preferably used or applied for formation of an electro-luminescence element (organic EL element).

### (Device)

In a first embodiment of a device of the present invention, the transparent conductive film of the present invention is used.

In a second embodiment of a device of the present invention, the sheet-shaped metal oxide microparticles of the present invention are used.

In a third embodiment of a device of the present invention, the device is produced using the dispersion of the present invention.

The device is not particularly limited and can be used for various devices. Particularly, the device can be preferably used for an electro-luminescence element (organic EL element) described below.

The organic EL element includes a positive electrode, a negative electrode, and an organic thin layer, which contains a light-emitting layer, between the positive electrode and the negative electrode, and may include other layers such as a protective layer according to the purpose.

The organic thin layer includes at least the light-emitting layer, and may further include, if necessary, a hole-injecting layer, hole-transporting layer, hole-blocking layer, electron-transporting layer, and the like.

The present dispersion can be preferably used for formation of transparent conductive films for the positive electrode and negative electrode.

The substrate for the positive electrode and negative electrode is not particularly limited and can be appropriately selected depending on the purpose. Examples thereof include those made of, for example, the following materials:
(1) glass such as quartz glass, alkali-free glass, transparent crystallized glass, PYREX (registered trademark) glass and sapphire,
(2) ceramics of Al₂O₃, MgO, BeO, ZrO₂, Y₂O₃, ThO₂, CaO, GGG (gadolinium gallium garnet), etc.,
(3) acrylic resins such as polycarbonate and polymethyl mathacrylate; vinyl chloride resins such as polyvinyl chloride and vinyl chloride copolymers; and thermoplastic resins such as polyarylate, polysulfone, polyethersulfone, polyimide, PET, PEN, fluorine resins, phenoxy resins, polyolefine resins, nylon, styrene resins and ABS resins,
(4) thermosetting resins such as epoxy resins, and
(5) metals.

Among them, a resin substrate is particularly preferred from the viewpoints of flexibility, light weight property and suitability to production.

As desired, these materials may be used in combination. Using materials appropriately selected from the above depending on the intended application, a flexible or rigid substrate having a shape of film, etc. can be formed.

The substrate may have any shape such as a disc shape, a card shape or a sheet shape. Also, the substrate may have a three-dimensionally laminated structure.

If necessary, the substrate may be treated to impart hydrophilicity to the surface thereof. Also, a hydrophilic polymer may be coated on the substrate surface. Further, a silane or titanium coupling agent may be coated on the substrate surface for hydrolysis. Such treatments allow the hydrophilic dispersion to be readily coated on the substrate.

The above hydrophilication treatment is not particularly limited and can be appropriately selected depending on the purpose. The hydrophilication treatment employs, for example, chemicals, mechanical roughening, corona discharge, flames, UV rays, glow discharge, active plasma or laser beams. Preferably, the surface tension of the substrate surface is adjusted to 30 dyne/cm or more through this hydrophilication treatment.

The hydrophilic polymer which is coated on the substrate surface is not particularly limited and can be appropriately selected depending on the purpose. Examples thereof include gelatin, gelatin derivatives, casein, agar, starch, polyvinyl alcohol, polyacrylic acid copolymers, carboxymethyl cellulose, hydroxyethyl cellulose, polyvinylpyrrolidone and dextran.

The thickness of the hydrophilic polymer layer is preferably 0.001 μm to 100 μm, more preferably 0.01 μm to 20 μm (in a dried state).

Preferably, a hardener is incorporated into the hydrophilic polymer layer to increase its film strength. The hardener is not particularly limited and can be appropriately selected depending on the purpose. Examples thereof include aldehyde compounds such as formaldehyde and glutaraldehyde; ketone compounds such as diacetyl ketone and cyclopentanedione; vinylsulfone compounds such as divinylsulfone; triazine compounds such as 2-hydroxy-4,6-dichloro-1,3,5-triazine; and isocyanate compounds described in, for example, U.S. Pat. No. 3,103,437.

The hydrophilic polymer layer can be formed as follows: the above hydrophilic compound is dissolved or dispersed in an appropriate solvent (e.g., water) to prepare a coating liquid; and using a coating method such as spin coating, dip coating, extrusion coating or bar coating, the thus-prepared coating liquid is coated on a substrate surface which had undergone a hydrophilication treatment.

If necessary, an undercoat layer may be provided between the substrate and the above hydrophilic polymer layer for improving adhesiveness therebetween.

The method by which the transparent conductive film is coated on the substrate may be any of the above coating techniques or a known printing method.

A conductive pattern can be formed as follows: the dispersion is patternwise applied on the substrate surface with an inkjet printer or dispenser, and the coated dispersion is dried.

The temperature in drying is preferably 200° C. or lower, more preferably 40° C. to 150° C. The drying unit employs, for example, an electric furnace, electromagnetic wave (e.g., microwave), infrared light, a hot plate, laser beams, electron beams, ion beams or heat rays. Preferably, the unit employs laser beams, electron beams, ion beams or heat rays, since they can finely and locally heat the formed pattern. Most preferably, the unit employs laser beams, since a laser device is relatively small and can easily apply energy rays.

Laser irradiation increases the density and electrical conductivity of the printed pattern and thus, a laser device is preferably used for formation of a printed wiring or electrode. The laser beams used may have any wavelengths falling within the regions of ultraviolet light, visible light and infrared light.

Typical examples of the laser include semiconductor lasers using, for example, AlGaAs, InGaAsP or GaN; Nd:YAG lasers; excimer lasers using, for example, ArF, KrF or XeCl; dye lasers; solid-state lasers such as ruby lasers; gaseous lasers using, for example, He—Ne, He—Xe, He—Cd, CO₂ or Ar; and free electron lasers. In addition, there may be employed surface emitting semiconductor lasers, and multimode arrays in which surface emitting semiconductor lasers are arranged one- or two-dimensionally. Laser beams emitted from the above lasers may be high-order harmonics such as second- or third-order harmonics, and may be applied continuously or in a pulsed manner at a plurality of times. Also, the irradiation energy is preferably determined so that metal nanoparticles are not substantially ablated but fused to one another.

### —Application—

The device of the present invention is widely applied to, for example, organic EL elements, electronic paper, liquid crystal display elements, plasma emission elements, solar cells, touch panels, electromagnetic wave shielding films; multilayered substrates such as IC substrates; transparent conductive films, wiring circuits on printed wiring boards; multilayered wiring boards such as build-up wiring boards, plastic wiring boards, printed wiring boards and ceramic wiring boards, and formation of various devices including a substrate.

### EXAMPLES

The present invention will next be described by way of examples, which should not be construed as limiting the present invention thereto.

The mean particle diameter, width (minor axis length/diameter), length (major axis length), and thickness of metal microparticles and silver nanowires are measured as follows.

### <Mean Particle Diameter, Width (Minor Axis Length/Diameter), Length (Major Axis Length), and Thickness of Metal Microparticles and Silver Nanowires>

The mean particle diameter, width, and length of metal nanoparticles and silver nanowires were determined through observation with a transmission electron microscope (TEM) (product of JASCO Corporation, JEM-2000FX).

The thickness of sheet and silver nanowires was determined with an atomic force microscope (AFM) (product of Digital Instruments, Inc., Nano Scope III).

### Production Example 1

### —Preparation of Silver Nanowires 1—

170 ml of ethylene glycol was heated at 160° C. for one hour. 50 ml of ethylene glycol solution of 0.1 mM chloroplatinic acid (IV) hexahydrate was added thereto. Seperately, 1.70 g of silver nitrate and 2.25 g of polyvinyl pyrrolidone (weight-average molecular weight 40,000) were dissolved in 200 ml of ethylene glycol. The resulting solution was added at a rate of 6 ml per minute. After the addition, the mixture was further heated at 160° C. for 30 minutes and then cooled to room temperature. Ethanol was added to the mixture, followed by centrifugation to purify the product. The product was dispersed by the addition of N,N-dimethylformamide to thereby prepare a dispersion containing 2% Ag by mass.

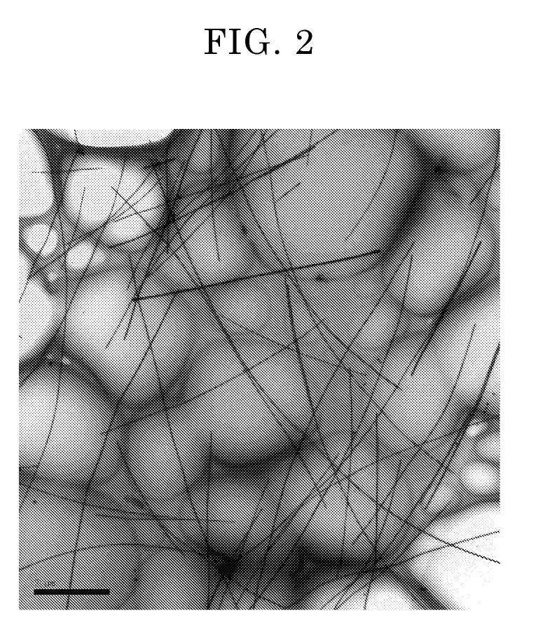

For the prepared dispersion, the length and width of the silver nanowires were measured and an aspect ratio was determined. It was found that silver nanowires 1 were formed that have a length (major axis length) of several μm, a width (minor axis diameter) of 50 nm, and an aspect ratio of 20 to 100 (FIG. 2).

### Production Example 2

### —Preparation of Ag Nanoparticles 1—

3.4 g of silver nitrate and 4.2 g of polyvinylpyrrolidone (weight-average molecular weight 40,000) were dissolved in 200 ml of water. To this solution, was added 20 ml of 2-diethylaminoethanol and stirred for 20 minutes to obtain a yellowish brown reaction product. Ethanol was added to the mixture, followed by centrifugation to purify the product. The product was dispersed by the addition of N,N-dimethylformamide to thereby prepare a dispersion containing 2% Ag by mass.

Ag nanoparticles 1 with a mean particle diameter of 8 nm were formed in the prepared dispersion.

### Production Example 3

### —Preparation of Metal Oxide Microparticles 1—

0.66 g of zinc acetate dihydrate and 30 mg of aluminum (III) isopropoxide were dissolved in 30 ml of ethylene glycol. To this solution, was added 1.20 g of sodium hydroxide dissolved in 60 ml of ethylene glycol. The mixture was stirred for 8 hours while heating at 170° C. After cooling to room temperature, ethanol was added to the mixture, followed by centrifugation to thereby purify the product. Then, the product was dispersed in a mixture of 60 vol. % isopropanol, 20 vol. % N-methylpyrrolidone, and 20 vol. % ethylene glycol using a nanomizer (product of Tokai Corporation) to prepare a dispersion containing 10% AZO by mass.

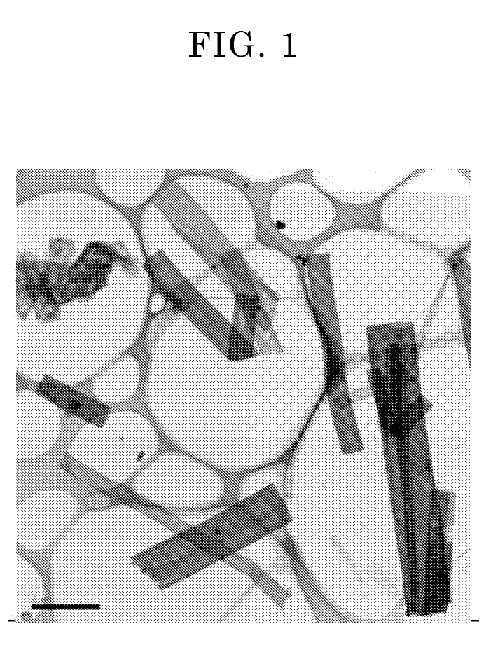

For the prepared dispersion, it was found that AZO (Al-doped ZnO) nanosheets were formed that had a width (minor axis length) and a length (major axis length) of 50 nm to several μm, respectively, and had an average thickness of 200 nm (FIG. 1). X-ray diffraction (XRD; product of Rigaku Denki Co., RINT2500) analysis revealed that these sheets were polycrystals of metal oxide microparticles 1 with a mean particle diameter of 12 nm.

### Production Example 4

### —Preparation of Metal Oxide Microparticles 2—

A dispersion was prepared in the same way as in the preparation of metal oxide microparticles 1, except that the heating time at 170° C. was reduced to 1 hour.

It was confirmed that AZO nanoparticles with a mean particle diameter of 8 nm as metal oxide microparticles 2 were formed in the prepared dispersion.

### Production Example 5

### —Preparation of Metal Oxide Microparticles 3—

0.75 g of zinc nitrate hexahydrate and 47 mg of aluminum nitrate enneahydrate were dissolved in 100 ml of water. To this solution, was slowly added 0.6 ml of 28% by mass aqueous ammonia and stirred for 3 hours. Then, the mixture was heated at 90° C. for 3 days and cooled to room temperature, followed by centrifugation to thereby purify the product. To the precipitate, was added cyclohexanol and dispersed.

As metal oxide microparticles 3, AZO micron particles (mean particle diameter: 1.4 μm, Al content: 4.2 atom %, concentration: 2% by mass) were obtained.

### Production Example 6

### —Preparation of Metal Oxide Microparticles 4—

7.25 g of indium (III) isopropoxide and 1.03 g of tin (IV) butoxide were weighed in a 500 ml three-necked flask and 200 ml of 2-ethoxyethanol (boiling point: 135° C.) was added to the flask. Under stirring with a stirrer, this solution was heated and the compounds were dissolved. 120 ml of cyclohexanol (boiling point: 161° C.) was added to the flask and heated under reflux to remove 2-ethoxyethanol. Further, this solution was refluxed for one hour to remove 50 ml of cyclohexanol and then cooled to room temperature. A light yellow viscous liquid was obtained. This liquid was placed in a glass container and the glass container was placed in a Hastelloy pressure vessel. This vessel was heated at 290° C. for one hour with an external heater. The pressure reached to around 3.5 MPa to 3.7 MPa. After cooling to room temperature, a liquid containing a grayish blue precipitate was obtained. A mixture of 40 vol. % isopropanol, 40 vol. % cyclohexanol, and 20 vol. % N-methylpyrrolidone was added and the precipitate was dispersed using a nanomizer (product of Tokai Corporation) to prepare a dispersion.

In the prepared dispersion, ITO nanoparticles with a mean particle diameter of 10 nm (10% concentration by mass) as metal oxide microparticles 4 were formed.

### Examples of the First and Second Embodiments

### <Preparation of Transparent Conductive Films Nos. 1 to 7 and 10 to 16>

As shown in Tables 1 and 2 below, coating solutions containing a combination of metal oxide microparticles 1 to 4 of Production Examples 3 to 6, silver nanowires 1 of Production Example 1, and silver nanoparticles 1 of Production Example 2 were prepared. Transparent conductive films Nos. 1 to 7 and 10 to 16 were prepared by applying the coating solutions onto a glass substrate, drying, and, if necessary, heating. Note that arylic resin (10% by mass with respect to metal oxide microparticles) was added to the coating solutions and dissolved.

### Example of the Second Embodiment

<Preparation of Transparent Conductive film No. 8>

γ-Methacryloxy propyl trimethoxy silane as a silane coupling agent was applied on both sides of a 300 μm thick plastic substrate (ZEONEX-48R, product of ZEON CORPORATION) to a thickness of 80 nm, and dried. A coating liquid was prepared by mixing a dispersion of AZO nanosheet as metal oxide microparticles 1 of Production Example 3 and a dispersion of Ag nanowires 1 of Production Example 1 so that the mass ratio of Ag to AZO was 0.05. The coating liquid was coated on one surface of the substrate so as to be Ag 0.1 g/m², and dried at 120° C. under nitrogen atmosphere to prepare transparent conductive film No. 8.

### Example of the Second Embodiment

<Preparation of Transparent Conductive film No. 9>

A transparent conductive film was prepared in the same way as in the preparation of transparent conductive film No. 8, except that a coating liquid, in which a dispersion of Ag nanowires 1 of Production Example 1 was mixed so that the mass ratio of Ag to AZO was 2.0, was used to thereby prepare transparent conductive film No. 9 (the coating amount, in terms of Ag, was 2.0 g/m²).

### Examples of the First and Second Embodiments

### <Preparation of Transparent Conductive Film No. 17>

A transparent conductive film was prepared in the same way as in the preparation of transparent conductive film No. 8, except that a coating liquid, in which a dispersion of AZO nanosheet as metal oxide microparticles 1 of Production Example 3 and a dispersion of Ag nanoparticles 1 were mixed so that the mass ratio of Ag to AZO was 0.05, was applied so as to be Ag 0.1 g/m² to thereby prepare transparent conductive film No. 17.

### Examples of the First and Second Embodiments

### <Preparation of Transparent Conductive Film No. 18>

A transparent conductive film was prepared in the same way as in the preparation of transparent conductive film No. 8, except that a coating liquid, in which a dispersion of AZO nanosheets as metal oxide microparticles 1 of Production Example 3 and a dispersion of Ag nanoparticles 1 of Production Example 2 were mixed so that the mass ratio of Ag to AZO was 2, was applied so as to be Ag 2 g/m² to thereby prepare transparent conductive film No. 18.

The surface resistivity and light transmittance of the obtained transparent conductive films were determined as shown below. The results are shown in Tables 1 and 2. The “No.” in the first column represents the No. of transparent conductive films.

### <Measurement of Surface Resistivity>

The surface resistivity of each transparent conductive film was determined by a four-probe method using a resistivity meter (product of Mitsubishi Chemical Corporation, Loresta-FP).

### <Light Transmittance>

The light transmittance of each transparent conductive film at a wavelength of 450 nm was determined using a spectrophotometer (UV2400-PC, product of Shimadzu Corporation) with air as a reference.

### —Results of Examples and Comparative Examples of the First Embodiment—

TABLE 1

| | | | | | Light | Surface | |
|---|---|---|---|---|---|---|---|
| | | | Mass | | transmittance | resistivity | |
| No. | Metal oxide particles | Silver particles | ratio | Heat treatment | (%) | (Ω/square) | |
| 2 | Metal oxide microparticles 2 | Silver nanowires 1 | 0.049 | 200° C., 30 minutes | 90 | 82 | Present invention |
| | (2.45) | (0.12) | | | | | |
| 3 | Metal oxide microparticles 4 | Silver nanowires 1 | 0.049 | 200° C., 30 minutes | 87 | 60 | Present invention |
| | (2.45) | (0.12) | | | | | |
| 7 | Metal oxide microparticles 4 | Silver nanowires 1 | 0.250 | None | 78 | 40 | Present invention |
| | (2.00) | (0.50) | | | | | |
| 11 | Metal oxide microparticles 2 | Silver nanoparticles 1 | 0.049 | 200° C., 30 minutes | 88 | 5900 | Comp. Example |
| | (2.45) | (0.12) | | | | | |
| 12 | Metal oxide microparticles 4 | Silver nanoparticles 1 | 0.049 | 200° C., 30 minutes | 85 | 3300 | Comp. Example |
| | (2.45) | (0.12) | | | | | |
| 14 | Metal oxide microparticles 4 | Silver nanoparticles 1 | 1.000 | 200° C., 30 minutes | 30 | 400 | Comp. Example |
| | (2.00) | (2.00) | | | | | |
| 15 | Metal oxide microparticles 4 | Silver nanoparticles 1 | 0.500 | 200° C., 30 minutes | 58 | 1020 | Comp. Example |
| | (2.00) | (1.00) | | | | | |
| 16 | Metal oxide microparticles 3 | Silver nanowires 1 | 0.250 | None | High haze | 35 | Comp. Example |
| | (2.00) | (0.50) | | | | | |
| 17 | Metal oxide microparticles 1 | Silver nanoparticles 1 | 0.05 | None | 89 | 1490 | Comp. Example |
| | (2.0) | (0.1) | | | | | |
| 18 | Metal oxide microparticles 1 | Silver nanoparticles 1 | 2.00 | None | 12 | 38 | Comp. Example |
| | (1.0) | (2.0) | | | | | |

The values in parentheses represent a coating amount (g/m²).
The “mass ratio” represents a mass ratio of the coating amount of silver particles relative to the coating amount of metal oxide microparticles.

Each transparent conductive film in Table 1 corresponds to Examples and Comparative Examples of the invention according to the first embodiment below.

“The transparent conductive film of the present invention, in a first embodiment, includes metal oxide microparticles having a mean particle diameter of 2 nm to 1,000 nm and silver nanowires having a minor axis diameter of 2 nm to 100 nm and an aspect ratio of 10 to 200.”

### —Results of Examples and Comparative Examples of the Second Embodiment—

TABLE 2

| | | | | | Light | Surface | |
|---|---|---|---|---|---|---|---|
| | | | Mass | | transmittance | resistivity | |
| No. | Metal oxide particles | Silver particles | ratio | Heating treatment | (%) | (Ω/square) | |
| 1 | Metal oxide microparticles 1 | Silver nanowires 1 | 0.049 | 200° C., 30 minutes | 90 | 45 | Present invention |
| | (2.45) | (0.12) | | | | | |
| 2 | Metal oxide microparticles 2 | Silver nanowires 1 | 0.049 | 200° C., 30 minutes | 90 | 82 | Comp. Example |
| | (2.45) | (0.12) | | | | | |
| 3 | Metal oxide microparticles 4 | Silver nanowires 1 | 0.049 | 200° C., 30 minutes | 87 | 60 | Comp. Example |
| | (2.45) | (0.12) | | | | | |
| 4 | Metal oxide microparticles 1 | Silver nanowires 1 | 1.000 | 200° C., 30 minutes | 74 | 18 | Present invention |
| | (1.00) | (1.00) | | | | | |
| 5 | Metal oxide microparticles 1 | Silver nanowires 1 | 0.500 | 200° C., 30 minutes | 74 | 9 | Present invention |
| | (2.00) | (1.00) | | | | | |
| 6 | Metal oxide microparticles 1 | Silver nanowires 1 | 0.008 | 200° C., 30 minutes | 92 | 460 | Present invention |
| | (1.00) | (0.02) | | | | | |
| 8 | Metal oxide microparticles 1 | Silver nanowires 1 | 0.05 | None | 91 | 42 | Present invention |
| | (2.0) | (0.1) | | | | | |
| 9 | Metal oxide microparticles 1 | Silver nanowires 1 | 2.00 | None | 52 | 6 | Present invention |
| | (1.0) | (2.0) | | | | | |
| 10 | Metal oxide microparticles 1 | Silver nanoparticles 1 | 0.049 | 200° C., 30 minutes | 88 | 1100 | Present invention |
| | (2.45) | (0.12) | | | | | |
| 11 | Metal oxide microparticles 2 | Silver nanoparticles 1 | 0.049 | 200° C., 30 minutes | 88 | 5900 | Comp. Example |
| | (2.45) | (0.12) | | | | | |
| 12 | Metal oxide microparticles 4 | Silver nanoparticles 1 | 0.049 | 200° C., 30 minutes | 85 | 3300 | Comp. Example |
| | (2.45) | (0.12) | | | | | |
| 13 | Metal oxide microparticles 1 | Silver nanoparticles 1 | 0.500 | 200° C., 30 minutes | 65 | 420 | Present invention |
| | (2.00) | (1.00) | | | | | |
| 14 | Metal oxide microparticles 4 | Silver nanoparticles 1 | 1.000 | 200° C., 30 minutes | 30 | 400 | Comp. Example |
| | (2.00) | (2.00) | | | | | |
| 15 | Metal oxide microparticles 4 | Silver nanoparticles 1 | 0.500 | 200° C., 30 minutes | 58 | 1020 | Comp. Example |
| | (2.00) | (1.00) | | | | | |
| 16 | Metal oxide microparticles 3 | Silver nanowires 1 | 0.250 | None | High haze | 35 | Comp. Example |
| | (2.00) | (0.50) | | | | | |
| 17 | Metal oxide microparticles 1 | Silver nanoparticles 1 | 0.05 | None | 89 | 1490 | Present invention |
| | (2.0) | (0.1) | | | | | |
| 18 | Metal oxide microparticles 1 | Silver nanoparticles 1 | 2.00 | None | 12 | 38 | Present invention |
| | (1.0) | (2.0) | | | | | |

The values in parentheses represent a coating amount (g/m²).
The “mass ratio” represents a mass ratio of the coating amount of silver particles relative to the coating amount of metal oxide microparticles.

Each transparent conductive film in Table 2 corresponds to Examples and Comparative Examples of the invention according to the second embodiment below.

“The transparent conductive film of the present invention, in a second embodiment, includes sheet-shaped metal oxide microparticles having a width and a length of 0.05 μm to 100 μm, respectively and having a thickness of 2 nm to 1,000 nm.”

The results in Tables 1 and 2 indicate that by using metal oxide microparticles and silver nanowires in combination as in transparent conductive films Nos. 1 to 7, transparent conductive films can be obtained that have low surface resistivity and high light transmittance compared to transparent conductive films in which silver nanoparticles are used in combination as in transparent conductive films Nos. 10 to 15. In addition, it was found that when metal oxide microparticles are in the form of nanosheet, greater effect can be obtained than when those are in the form of nanoparticles.

Also, transparent conductive film No. 16 was found to have deteriorated light transmittance since the mean particle diameter of metal oxide microparticles was too large.

Although transparent conductive films Nos. 8 and 9 were not subjected to heating after drying, they had high light transmittance and low surface resistivity.

In contrast, conventional transparent conductive film No. 17, in which Ag nanoparticles were used, had high surface resistivity. In addition, transparent conductive film No. 18, in which the coating amount of Ag was increased, had low surface resistivity, but the film was colored yellow to the extent that it causes problems in practical use.

### Examples of the Third Embodiment

### —Production of Organic Electro-Luminescence Element A (Comparative Product)—

Using a dispenser, a dispersion of silver nanowires 1 of Production Example 1 was coated in a width of 5 mm (coating amount of silver: 0.18 g/m²) on the central portion of a 0.7 mm-thick, 25 mm-square glass substrate, dried under nitrogen atmosphere and heated at 200° C. for 30 minutes to obtain transparent support substrate A with a surface resistivity of 12 Ω/square and a transmittance of 84%.

Next, a 40 nm thick film of N,N′-bis(3-methylphenyl)-N,N′-diphenylbenzidine (TPD), a 20 nm thick film of methine compound represented by the following formula, and a 40 nm thick film of 2,5-bis(1-naphthyl)-1,3,4-oxa-diazole were deposited in this order onto a transparent conductive layer (anode) of transparent support substrate A in a vacuum of 10⁻⁵ to 10⁻⁶ Torr under the condition where substrate temperature was room temperature. Then, a 50 nm thick film of magnesium:silver=10:1 was co-deposited onto this organic thin film in such a way to cross over the above conductive layer through a patterned mask giving an emission area of 5×5 mm square. Finally, a 50 nm thick film of silver was vacuum deposited to form cathode. In this way, organic electro-luminescence element A was produced.

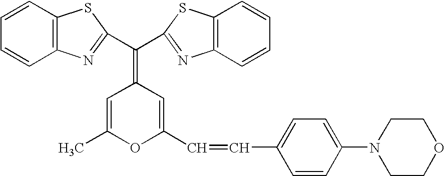

### —Production of Organic Electro-Luminescence Element B (Product of the Present Invention)—

A liquid was prepared by mixing a dispersion of ITO nanoparticles as metal oxide microparticles 4 of Production Example 6 and a dispersion of silver nanowires 1 of Production Example 1. The prepared liquid was coated on a glass substrate in the same way as described above (coating amount of silver: 0.16 g/m², coating amount of ITO: 1.2 g/m², and mass ratio of Ag to ITO: 0.13), drided, and heated to obtain transparent support substrate B with a surface resistivity of 14 Ω/square and a transmittance of 85%. Organic electro-luminescence element B was produced in the same way as organic electro-luminescence element A, except that transparent support substrate B was used instead of transparent support substrate A.

### <Evaluation>

Direct voltage was applied to both organic electro-luminescence elements A and B using Source-Measure Unit 2400 (product of TOYO Corporation). Although organic electro-luminescence element B emitted red light at 5V to 6V, organic electro-luminescence element A did not emit light. This indicates that when ITO nanoparticles and silver nanowires are contained in the same layer as anode of organic electro-luminescence element, effects in electrical conductivity, transparency, and light-emitting performance can be exhibited.

The transparent conductive film and dispersion of the present invention have high transparency and conductivity, and have excellent storage stability. Thus, the present conductive film and dispersion are used for, for example, transparent electrodes in organic EL elements, electronic paper, liquid crystal display elements, plasma emission elements, etc.; transparent electrodes for solar cells, heat-reflecting films, antistatic films, transparent heating elements, touch panels, electromagnetic wave shielding films, and the like. The present conductive film and dispersion are widely applied to, for example, organic EL elements, electronic paper, liquid crystal display elements, plasma emission elements, solar cells, touch panels, electromagnetic wave shielding films; multilayered substrates such as IC substrates; transparent conductive films, wiring circuits on printed wiring boards; multilayered wiring boards such as build-up wiring boards, plastic wiring boards, printed wiring boards and ceramic wiring boards, and formation of various devices including a substrate.

What is claimed is:

1. A transparent conductive film comprising:
metal oxide microparticles; and
silver nanowires,
wherein the metal oxide microparticles have a mean particle diameter of 2 nm to 1,000 nm, and the silver nanowires have a minor axis diameter of 2 nm to 100 nm and an aspect ratio of 10 to 200.

2. The transparent conductive film according to claim 1, wherein a mass ratio of the silver nanowires to the metal oxide microparticles is 0.001 to 1.

3. The transparent conductive film according to claim 1, wherein the metal oxide microparticles are metal oxides each of which contains at least two metals selected from the group consisting of Zn, Al, Ga, In, Sn and Sb.

4. The transparent conductive film according to claim 1, wherein the silver nanowires are present in an amout of 0.01 g to 1 g per 1 m².

5. A transparent conductive film comprising:
sheet-shaped metal oxide microparticles,
wherein a width and a length of the sheet-shaped metal oxide microparticles are 0.05 μm to 100 μm, respectively, and a thickness of the sheet-shaped metal oxide microparticles is 2 nm to 1,000 nm.

6. The transparent conductive film according to claim 5, further comprising silver nanowires.

7. The transparent conductive film according to claim 6, wherein the silver nanowires have a width of 2 nm to 100 nm and an aspect ratio of 10 to 200.

8. The transparent conductive film according to claim 6, wherein a mass ratio of the silver nanowires to the metal oxide microparticles is 0.001 to 1.

9. The transparent conductive film according to claim 5, wherein the metal oxide microparticles are metal oxides each of which contains at least two metals selected from the group consisting of Zn, Al, Ga, In, Sn and Sb.

10. The transparent conductive film according to claim 6, wherein the silver nanowires are present in an amout of 0.01 g to 1 g per 1 m².

11. A metal oxide microparticle, wherein the metal oxide microparticle has a sheet shape, and wherein a width and a length of the metal oxide microparticle are 0.05 μm to 100 μm, respectively, and a thickness of the metal oxide microparticle is 2 nm to 1,000 nm.

12. The metal oxide microparticle according to claim 11, wherein the metal oxide microparticle comprise is a metal oxide which contains at least two metals selected from the group consisting of Zn, Al, Ga, In, Sn and Sb.
